(19) United States
(12) Patent Application Publication
(10) Pub. No.: US 2024/0210455 A1
(43) Pub. Date: Jun. 27, 2024

(54) DARK TEST METHOD AND ABNORMALITY DIAGNOSIS APPARATUS

(71) Applicant: OKUMA Corporation, Niwa-gun (JP)

(72) Inventor: Yoshimasa EGI, Niwa-gun (JP)

(21) Appl. No.: 18/537,094

(22) Filed: Dec. 12, 2023

(30) Foreign Application Priority Data
Dec. 22, 2022 (JP) 2022-205495

(51) Int. Cl. G01R 29/02

(52) U.S. Cl. CPC G01R 29/02

(57) ABSTRACT

A dark test method for diagnosing presence or absence of an abnormality in an output switch circuit configured to output a voltage signal for switching ON and OFF an output device includes performing a test process including: outputting, to the output switch circuit a switch signal having an OFF pulse form with a diagnosis pulse width; and determining whether or not a response pulse having an OFF pulse form can be detected from an output detection signal obtained by digitally converting the voltage signal output from the output switch circuit. The test process is repeated while gradually increasing the diagnosis pulse width until the response pulse can be detected. It is determined that the output switch circuit is abnormal when the diagnosis pulse width reaches or exceeds a specified upper limit value.

### CROSS REFERENCE TO RELATED APPLICATION

The present invention claims priority under 35 U.S.C. § 119 to Japanese Patent Application No. 2022-205495 filed on Dec. 22, 2022, the entire content of which is incorporated herein by reference.

### TECHNICAL FIELD

The present specification discloses a dark test method and an abnormality diagnosis apparatus for diagnosing abnormality in an output switch circuit configured to output a voltage signal to an output device.

### BACKGROUND

A PLC (programmable logic controller) used in the field of FA (factory automation) for automating factory production processes is an apparatus for performing control of controlled devices. In an output device of such a PLC, it is required to periodically diagnose whether, when an emergency stop is requested, the PLC can control an output to the safe side (or toward the output OFF state) and stop operation of the connected output device.

In an output device (such as a solenoid valve) that repeats turning ON and OFF in a usual state of operation, abnormality diagnosis can be performed at an instance when an output OFF command is issued. On the other hand, in the case of an output device that is always in the output ON state while in operation, such as an STO cancellation input for a servo drive unit with an STO (safe torque OFF) function, there is no instance of issuing an output OFF command while in a state of long-time continuous operation, and abnormality diagnosis cannot be performed.

For this reason, it is typical to use a technique called a dark test or pulse test, in which abnormality diagnosis is performed by outputting a short OFF pulse to which the output device does not respond.

FIG. 5 is a block diagram showing a configuration of an abnormality diagnosis apparatus having a dark test function. A dark test method will now be described by reference to FIG. 5.

An output controller 1 outputs an output switch signal to an output switch circuit 2 based on an output command output by a logic unit (not shown in drawing) and a diagnosis request output by an output diagnosis unit 4b. Further, the output controller 1 outputs, to the output diagnosis unit 4b, an output status indicating the content of the output switch signal being output at present. The output switch signal is maintained in an OFF state when the output command is OFF and is varied according to the diagnosis request when the output command is ON. More specifically, when the output command is ON and the diagnosis request is OFF, the output switch signal is maintained in an ON state, and when the output command is ON and the diagnosis request is ON, the output switch signal is varied to have an OFF pulse form in which the signal momentarily becomes OFF. The output status includes the following three statuses: “output ON” indicating that the output switch signal is maintained in the ON state; “output OFF” indicating that the output switch signal is maintained in the OFF state; and “diagnosis pulse output” indicating that the output switch signal is varied to have the OFF-pulse form.

The output switch circuit 2 is a circuit interposed between an output device power supply 6 and an output device 5 and includes a switch. Based on the output switch signal output by the output controller 1, the output switch circuit 2 performs switching operation of the switch, and outputs an output signal, which is a voltage signal, to the output device 5. In a steady state of operation, when the output switch signal is ON, the output signal is an output voltage of the output device power supply 6, and when the output switch signal is OFF, the output signal is 0 V. Here, the switch is, for example, an electric switch composed of a semiconductor.

An output detection circuit 3 converts the output signal output by the output switch circuit 2 into a digital signal, and outputs the digital signal as an output detection signal to the output diagnosis unit 4b.

The output diagnosis unit 4b performs diagnosis of the output switch circuit 2 based on the output detection signal output by the output detection circuit 3 and the output status output by the output controller 1. That is, when there is inconsistency between the output status and the output detection signal, a diagnosis unit 41b outputs an abnormality detection signal indicating an abnormality in the output switch circuit 2. When the abnormality detection signal is output, various error processing steps are carried out in the logic unit (not shown in the drawing). The output diagnosis unit 4b also outputs a diagnosis request and a diagnosis pulse width to the output controller 1. For example, a diagnosis pulse request unit 42b outputs a diagnosis request ON signal to the output controller 1 at times such as when the “output ON” status has continued for a certain period of time. In addition, the diagnosis pulse request unit 42b outputs, to the output controller 1, a value such as one set in advance in a pulse width storage unit 44 as the diagnosis pulse width.

The output device 5 is, for example, a solenoid valve, a servo drive unit with an STO function, or the like.

The output device power supply 6 is, for example, a drive power supply for a solenoid valve, an input power supply for an STO cancellation terminal of a servo drive unit with an STO function, or the like.

Operation performed when the output controller 1 outputs a diagnosis pulse as the output switch signal will now be described.

When the diagnosis request is ON, the output controller 1 outputs, as the output switch signal, a diagnosis pulse (or OFF pulse) shown as the output switch signal in FIG. 3. The OFF pulse width of the diagnosis pulse is the diagnosis pulse width output by the output diagnosis unit 4b. An output signal output by the output switch circuit 2 in response to the diagnosis pulse of FIG. 3 has, for example, a waveform shown as the output signal in FIG. 3, due to response delay of the circuit. Further, the output signal is digitally converted by the output detection circuit 3, and the obtained output detection signal is a digital signal having an OFF pulse form (hereinafter referred to as a “response pulse”), such as one shown as the output detection signal in FIG. 3. When the output status is “diagnosis pulse output”, the diagnosis unit 41b of the output diagnosis unit 4b checks whether or not the output detection signal includes a response pulse. When the output detection signal includes a response pulse, the output diagnosis unit 4b diagnoses that the output signal can be turned OFF, or in other words, that the output switch circuit 2 is normal. On the other hand, when the output detection signal includes no response pulse, the output diagnosis unit 4b outputs an abnormality detection signal indicating an abnormality in the output switch circuit 2.

Here, if the pulse width of the diagnosis pulse is too short, the output signal would have a waveform that is not fully turned OFF as shown, for example, in the output signal in FIG. 4. At that time, if the output signal does not become less than the threshold voltage of the output detection circuit 3, the output detection signal would include no response pulse as shown in the output detection signal in FIG. 4, so that the output diagnosis unit 4b would erroneously detect an abnormality in the output switch circuit 2. On the other hand, if the pulse width of the diagnosis pulse is too long, the output device 5 would respond to the turning OFF of the output signal.

In other words, in a dark test, the pulse width of the diagnosis pulse is important, and it is necessary to appropriately set the pulse width of the diagnosis pulse according to the response characteristic of the output switch circuit 2, the type of the connected output device 5, and the like. As a method for setting the pulse width of the diagnosis pulse, for example, Patent Document 1 discloses a technique of outputting diagnosis pulses using a plurality of pulse widths, comparing pulse widths of output detection signals corresponding to the respective pulse widths of the diagnosis pulses, and performing auto-tuning to determine a pulse width that would not be erroneously detected.

### CITATION LIST

### Patent Literature

Patent Document 1: WO 2019/069433 A

The diagnosis pulse width for a dark test is set short in order to reduce influence on the output device. However, if the diagnosis pulse width is too short, an abnormality tends to be erroneously detected, due to individual differences of the connected output device, individual differences of semiconductor components constituting the output switch circuit 2, and the like. Accordingly, in order to avoid erroneous detection of an abnormality, it is necessary to set a diagnosis pulse width having a sufficient margin. Further, in determining the size of the margin, it is necessary to consider variations and temperature-based fluctuations in characteristics and the like of the semiconductor components constituting the output switch circuit 2, and work of determining an appropriate margin based on design and evaluation is conventionally required.

The present specification discloses a dark test method and a diagnosis apparatus for performing a dark test using the smallest possible diagnosis pulse width.

### SUMMARY

In a dark test method for diagnosing presence or absence of an abnormality in an output switch circuit configured to output a voltage signal for switching an output device ON and OFF, a test process is performed including: outputting, to the output switch circuit, a switch signal having an OFF pulse form with a diagnosis pulse width; and determining whether or not a response pulse having an OFF pulse form can be detected from an output detection signal obtained by digitally converting the voltage signal output from the output switch circuit. The test process is repeated while gradually increasing the diagnosis pulse width until the response pulse can be detected. When the diagnosis pulse width reaches or exceeds a specified upper limit value, it is diagnosed that the output switch circuit is abnormal.

Further, an abnormality diagnosis apparatus for diagnosing presence or absence of an abnormality in an output switch circuit configured to output a voltage signal for switching ON and OFF an output device includes: an output detection circuit configured to acquire an output detection signal obtained by digitally converting the voltage signal; an output controller configured to output, to the output switch circuit, a switch signal indicating ON or OFF; and an output diagnosis unit configured to execute a dark test for diagnosing presence or absence of an abnormality in the output switch circuit. In the dark test, the output diagnosis unit performs a test process of instructing the output controller to output an output switch signal having an OFF pulse form with a diagnosis pulse width, and determining whether or not a response pulse having an OFF pulse form can be detected from the output detection signal and repeats the test process while gradually increasing the diagnosis pulse width until the response pulse can be detected. Further, the output diagnosis unit diagnoses that the output switch circuit is abnormal when the diagnosis pulse width reaches or exceeds a specified upper limit value.

By repeating the test process while increasing the diagnosis pulse width, the dark test can be carried out using the smallest possible diagnosis pulse width according to variations and temperature-based fluctuations in characteristics of the circuit. Furthermore, since the diagnosis pulse width for the dark test can be automatically adjusted according to variations and temperature-based fluctuations in characteristics of the circuit, modifications in parameters of the dark test are unnecessary even when a circuit component has been replaced due to being out of production or for other reasons such as purchase of an alternative product.

### BRIEF DESCRIPTION OF DRAWINGS

Embodiment(s) of the present disclosure will be described based on the following figures, wherein:

FIG. 1 is a flowchart illustrating a flow of a dark test method;

FIG. 2 is a block diagram showing a configuration of a diagnosis apparatus having a dark test function;

FIG. 3 is a diagram illustrating an example relationship between an output switch signal and an output detection signal in a dark test;

FIG. 4 is a diagram illustrating an example relationship between an output switch signal and an output detection signal in a dark test; and

FIG. 5 is a block diagram showing a conventional example of a diagnosis apparatus having a dark test function.

### DESCRIPTION OF EMBODIMENTS

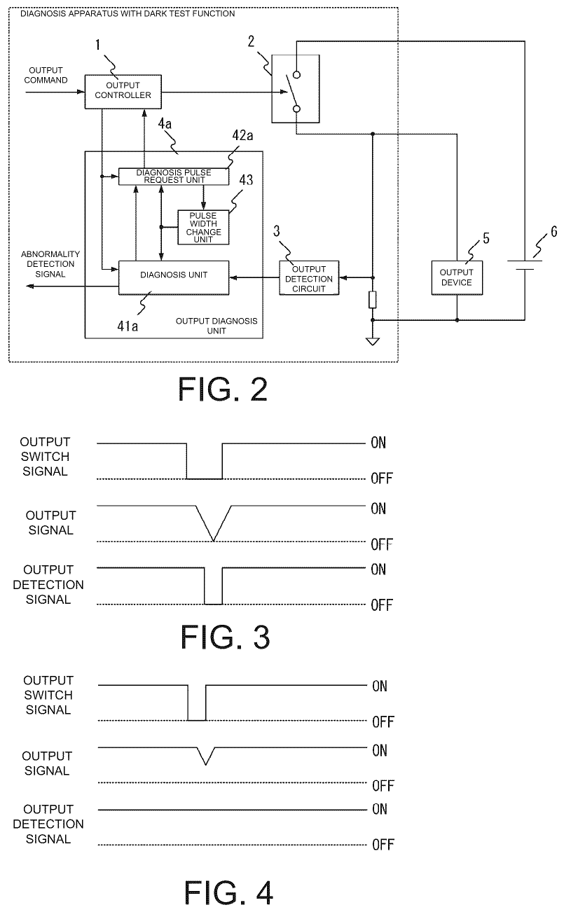

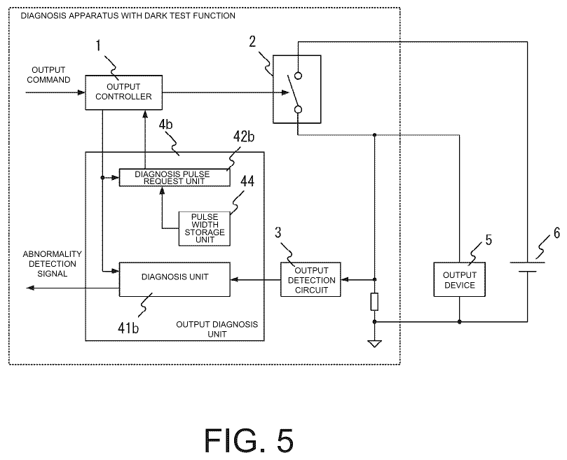

FIG. 2 is a block diagram showing a configuration of a diagnosis apparatus. Elements in common with the conventional example described above using FIG. 5 are labeled with like numerals, and description thereof will not be repeated.

An output diagnosis unit 4a performs diagnosis of the output switch circuit 2 based on an output detection signal output by the output detection circuit 3 and an output status output by the output controller 1. That is, when there is inconsistency between the output status and the output detection signal, a diagnosis unit 41a outputs an abnormality detection signal indicating an abnormality in the output switch circuit 2. When the abnormality detection signal is output, various error processing steps are executed in a logic unit (not shown in the drawing). Further, the output diagnosis unit 4a outputs a diagnosis request and a diagnosis pulse width to the output controller 1. For example, a diagnosis pulse request unit 42a outputs a diagnosis request ON signal to the output controller 1 when, as the output status, “output ON” has continued for a certain period of time, and when the diagnosis unit 41a has requested re-execution of the test process. Further, the diagnosis pulse request unit 42a outputs, to the output controller 1, a value set in a pulse width change unit 43 as the diagnosis pulse width.

The diagnosis pulse request unit 42a updates the diagnosis pulse width according to a factor based on which the diagnosis request ON signal is output and sets the updated value in the pulse width change unit 43. In the case where the output status is “output ON” or “output OFF”, when there is inconsistency between the output status and the output detection signal, the diagnosis unit 41a outputs an abnormality detection signal. Further, in the case where the output status is “diagnosis pulse output”, when no response pulse (or OFF pulse) can be obtained from the output detection signal and the diagnosis pulse width is less than an upper limit value, the diagnosis unit 41a requests re-execution of the test process to the diagnosis pulse request unit 42a, and when no response pulse can be obtained and the diagnosis pulse width is greater than or equal to the upper limit value, the diagnosis unit 41a outputs an abnormality detection signal.

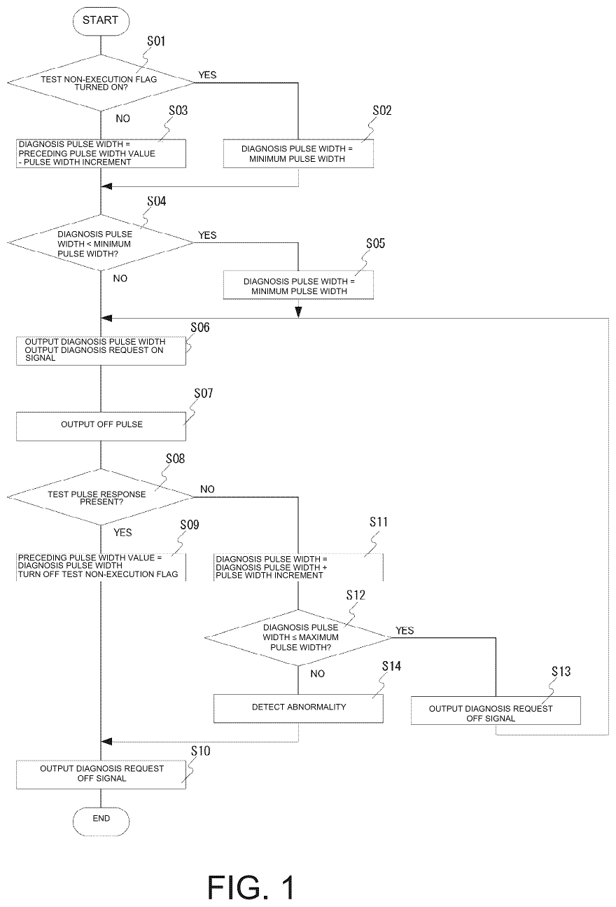

FIG. 1 is a flowchart illustrating an example dark test. The output controller 1 and the output diagnosis unit 4a shown in the block diagram of FIG. 2 execute steps shown in the flowchart of FIG. 1.

The diagnosis pulse request unit 42a of the output diagnosis unit 4a starts the dark test process at times such as when, for example, “output ON” of the output status output by the output controller 1 has continued for a certain period of time and proceeds to step S01. Hereinafter, steps up to step S06 are executed by the output diagnosis unit 4a.

In step S01, the diagnosis pulse request unit 42a checks a test non-execution flag and determines whether or not the current instance is an initial dark test. The test non-execution flag is a flag that is turned ON in an initialization process performed when turning power ON. When the test non-execution flag is ON, the process proceeds to step S02, and when the test non-execution flag is OFF, the process proceeds to step S03.

Step S02 is a step of determining an initial value of the diagnosis pulse width upon execution of an initial dark test. In step S02, the diagnosis pulse request unit 42a sets a pre-specified minimum pulse width as the diagnosis pulse width in the pulse width change unit 43, and the process proceeds to step S04.

Step S03 is a step of determining an initial value of the diagnosis pulse width upon execution of second and subsequent dark tests. In step S03, the diagnosis pulse request unit 42a sets, as the diagnosis pulse width in the pulse width change unit 43, a value obtained by subtracting a pre-specified pulse width increment from a preceding pulse width value which has been stored in step S09 during execution of a preceding dark test, and the process proceeds to step S04.

Step S04 and step S05 are a processing in which, in the case where the diagnosis pulse width set in the pulse width change unit 43 in S03 is less than a minimum pulse width, the pulse width change unit 43 limits the diagnosis pulse width to the minimum pulse width. After the limiting processing, the process proceeds to step S06. Here, the minimum pulse width is a pre-specified value.

In step S06, the diagnosis pulse request unit 42a outputs, to the output controller 1, a diagnosis request ON signal and the diagnosis pulse width set in the pulse width change unit 43, and the process proceeds to step S07.

Step S07 is a processing executed by the output controller 1. In accordance with the diagnosis request, the output controller 1 outputs a diagnosis pulse having the diagnosis pulse width, and the process proceeds to step S08. Step S08 and subsequent steps are executed by the output diagnosis unit 4a.

In step S08, the diagnosis unit 41a determines presence or absence of a response pulse with respect to the diagnosis pulse output in step S07 and notifies the result to the diagnosis pulse request unit 42a. When the output detection signal includes a response pulse, the process proceeds to S09, and when no response pulse is included, the process proceeds to S11.

Step S09 is processing executed in the case where the dark test has been successfully completed. When a response pulse corresponding to the diagnosis pulse is present, the diagnosis pulse request unit 42a recognizes that the dark test has been successfully completed. Further, the diagnosis pulse request unit 42a stores the diagnosis pulse width used in successfully completing the dark test as a preceding pulse width value and turns OFF the test non-execution flag. Subsequently, the process proceeds to S10.

In step S10, the diagnosis pulse request unit 42a turns OFF the diagnosis request, and the dark test is completed.

Step S11 and step S12 are processing for increasing the diagnosis pulse width when no response pulse is present in step S08. In step S11, the diagnosis pulse request unit 42a adds a pulse width increment to the diagnosis pulse width output by the pulse width change unit 43 and resets the obtained value in the pulse width change unit 43. In step S12, the diagnosis unit 41a compares the reset diagnosis pulse width to a maximum pulse width. When the diagnosis pulse width is less than or equal to the maximum pulse width, the process proceeds to step S13. In step S13, the diagnosis pulse request unit 42a turns OFF the diagnosis request, and then again carries out the process from step S06 onward using the reset diagnosis pulse width. On the other hand, when the diagnosis pulse width exceeds the maximum pulse width, the process proceeds to step S14. Here, the maximum pulse width is a pre-specified value.

Step S14 is a processing executed when the diagnosis pulse width for the diagnosis pulse exceeds the maximum pulse width. In step S14, the diagnosis unit 41a outputs an abnormality detection signal. The logic unit (not shown in drawing) detects an abnormality in the output switch circuit 2 based on the abnormality detection signal and performs various error processing steps.

By configuring the processing performed by the output controller 1 and the output diagnosis unit 4a as described above, the dark test can always be executed using the smallest possible pulse width even when there are variations and temperature-based fluctuations in characteristics of the output switch circuit 2. The maximum pulse width may be set, for example, in accordance with an output device having the slowest response among output devices intended to be connected to the output switch circuit 2. In that case, in a situation where an output device having fast response is connected, if the diagnosis pulse width is equal to the maximum pulse width, the output device would obviously respond to the diagnosis pulse. However, when the output switch circuit 2 is normal, the diagnosis pulse width is only increased to a pulse width to which the output device does not respond, so that there should be no influence. Further, for example, when the output switch circuit 2 has an abnormality and cannot output an OFF signal, the diagnosis pulse cannot be output, so that the output device does not respond. At that time, the abnormality is detected in step S14 of FIG. 1, and appropriate error processing is performed.

The above-described configuration is simply one example, and the configuration of the output device 5 and the output device power supply 6 may be changed as appropriate. That is, the diagnosis apparatus of FIG. 2 may be provided in a single device with the output device 5 and the output device power supply 6 or may be provided in devices separate from each other. For example, the technique disclosed in the present specification may be used as a dark test method for testing an STO function in a servo drive unit in which the STO function is executed by cutting off a primary-side power supply of a gate signal transmitting photocoupler configured to drive a power semiconductor device. For example, the output device 5 of FIG. 2 is a gate signal transmitting photocoupler, the output device power supply 6 is a primary-side power supply of the photocoupler, the output switch circuit 2 is a cut-off circuit for the primary-side power supply of the photocoupler, and all of these elements may be arranged within the same device.

### REFERENCE SIGNS LIST

1 output controller; 2 output switch circuit; 3 output detection circuit; 4a, 4b output diagnosis unit; 5 output device; 6 output device power supply; 41a, 41b diagnosis unit; 42a, 42b diagnosis pulse request unit; 43 pulse width change unit; 44 pulse width storage unit.

1. A dark test method for diagnosing presence or absence of an abnormality in an output switch circuit configured to output a voltage signal for switching ON and OFF an output device, comprising
performing a test process including:
outputting, to the output switch circuit, a switch signal having an OFF pulse form with a diagnosis pulse width; and
determining whether or not a response pulse having an OFF pulse form can be detected from an output detection signal obtained by digitally converting the voltage signal output from the output switch circuit, wherein
the test process is repeated while gradually increasing the diagnosis pulse width until the response pulse can be detected, and
determining that the output switch circuit is abnormal when the diagnosis pulse width reaches or exceeds a specified upper limit value.

2. The dark test method according to claim 1, comprising
storing, as a preceding pulse width value, the diagnosis pulse width used at a time when the response pulse could be detected, and at a time of a subsequent dark test, using the preceding pulse width value as a reference to determine the diagnosis pulse width for an initial test process.

3. An abnormality diagnosis apparatus for diagnosing presence or absence of an abnormality in an output switch circuit configured to output a voltage signal for switching ON and OFF an output device, comprising:
an output detection circuit configured to acquire an output detection signal obtained by digitally converting the voltage signal;
an output controller configured to output, to the output switch circuit, a switch signal indicating ON or OFF; and
an output diagnosis unit configured to execute a dark test for diagnosing presence or absence of an abnormality in the output switch circuit, wherein
in the dark test, the output diagnosis unit performs a test process which involves instructing the output controller to output an output switch signal having an OFF pulse form with a diagnosis pulse width, and determining whether or not a response pulse having an OFF pulse form can be detected from the output detection signal, repeats the test process while gradually increasing the diagnosis pulse width until the response pulse can be detected, and diagnoses that the output switch circuit is abnormal when the diagnosis pulse width reaches or exceeds a specified upper limit value.

4. The abnormality diagnosis apparatus according to claim 3, wherein
the output diagnosis unit stores, as a preceding pulse width value, the diagnosis pulse width used at a time when the response pulse could be detected, and at a time of a subsequent dark test, uses the preceding pulse width value as a reference to determine the diagnosis pulse width for an initial test process.
